(19) United States
(12) Patent Application Publication
(10) Pub. No.: US 2024/0113147 A1
(43) Pub. Date: Apr. 4, 2024

(54) OPTO-ELECTRICAL INSULATED FRONTSIDE ILLUMINATED 3D DIGITAL SILICON PHOTOMULTIPLIER

(71) Applicant: SOCPRA SCIENCES ET GENIE S.E.C., Sherbrooke (CA)

(72) Inventors: Jean-François PRATTE, St-Catherine de Hatley (CA); Samuel PARENT, Sherbrooke (CA); Serge CHARLEBOIS, Cookshire-Eaton (CA); Henri DAUTET, Greenfield Park (CA)

(21) Appl. No.: 18/526,681

(22) Filed: Dec. 1, 2023

Related U.S. Application Data
(63) Continuation of application No. PCT/CA2022/050911, filed on Jun. 8, 2022.
(60) Provisional application No. 63/208,858, filed on Jun. 9, 2021.

(51) Int. Cl. H01L 27/146; H01L 31/107

(52) U.S. Cl. CPC H01L 27/14636; H01L 27/1463; H01L 31/107

(57) ABSTRACT

This disclosure pertains to a new thinned down frontside illuminated 3D SiPM architecture, e.g. a Photon-to-Digital Converter, with direct interconnect layers between the SPAD and the CMOS. The described architecture removes the need to have through-silicon-vias. Additionally, this new architecture also provides low jitter operation of the SPADs. The architecture described herein, with extended isolation trenches through the entire thickness of the thinned down SPAD substrate, enables both the SPAD cell to be electrically and optically isolated from the other SPAD cells. As such, the crosstalk is minimized and direct backside connection is possible.

This patent application is a continuation of PCT patent application serial number PCT/CA2022/050911 filed Jun. 8, 2022, designating the US, now pending and claims priority of U.S. provisional patent application 63/208,858 filed on 9 Jun. 2021, the contents of which are hereby incorporated by reference.

### TECHNICAL FIELD

The present patent application relates to the field of single-photon avalanche diode photodetectors, and more particularly to frontside illuminated 3D digital silicon photomultipliers (photon-to-digital converters).

### BACKGROUND

Analog silicon photomultipliers (SiPM) were introduced in the first decade of 2000 and have since revolutionized the field of radiation instrumentation by replacing both avalanche photodiodes and photomultiplier tubes in many detector systems. These photodetectors are used in a vast number of applications, ranging from PET imaging, Cherenkov telescope arrays (CTA), large scale liquid xenon or argon detectors, LiDAR, etc. The ability to design the photodetector to operate in the desired wavelength band enables their use in specific applications.

The single-photon avalanche diode (SPAD) is a photodiode polarized above the breakdown voltage in a quiet (zero current) metastable state. Once a photoelectron or a thermally excited or released electron enters the photodetector, the metastable state is lost as the current rises swiftly to a detectable macroscopic steady level. Once triggered, the high current streaming through the photodiode is quenched by an external circuit (the bias potential is reduced below the breakdown voltage). These SPADs are the basic unit cells of all SiPM technologies.

The initial SiPM designs were analog and mainly integrated in 2D. Analog designs feature passive resistor quenching and give out a linear response by performing an analog sum of the current in each SPAD-resistor pairs. A 2D digital SiPM is composed of an array of SPADs and quenching circuits integrated together in a CMOS or dedicated technology.

Although 2D digital SiPM has numerous advantages, a digital 3D integrated SiPM structure was quickly introduced by the MIT Lincoln Laboratory. This new structure allowed the SPAD cells to be directly connected to any desired readout electronics in a CMOS wafer. The 3D structure integrates heterogeneous microelectronics and optoelectronics technologies vertically (in the third dimension), such that the single-photon avalanche diodes array and the front-end electronics are stacked on distinct physical tiers. Moreover, 3D opens the door to uniform routing trace length and electrical path impedance between the SPADs and its readout electronics. With the use of time-to-digital converters this results in a uniform timing performance for each individual SPAD of the array.

It is known that the propagation of the avalanche from the position where a photon was absorbed to the electrical contacts on the periphery of the SPAD cause large fluctuation (jitter) of the time the electrical signal can be detected. By providing a high conductivity layer (metallic or not) uniformly distributed under the SPAD junction, one can efficiently reduce time jitter because avalanches have to propagate over a uniform distance within the semiconductor wherever the photon was absorbed. Therefore, with respect to timing resolution, 3D integration is the only architecture scheme that allows for a SPAD of ideal geometry to be integrated at short and uniform distance from a low jitter quenching circuit with a stabilized low jitter TDC and further allows for signal processing to use address-based calibration data to compensate time-stamp non-uniformity.

However, many issues still exist with the current SPAD arrays. One such issue is that, by nature, a SPAD response is identical whether the initial carrier is photogenerated (signal) or thermally generated (noise). Other sources of noise exists such as band-to-band tunneling generated noise and after pulsing noise. Also, in a SPAD array, the avalanche from a single SPAD triggering emits secondary photons, which can trigger surrounding cells (cross talk noise). This is a significant limitation in applications where discriminating between real photon detection and noise is essential (e.g. low background particle physics experiment or positron emission tomography).

Additionally, the 3D SiPM architectures found in the prior art typically include a through-silicon-vias (TSV) process for frontside illumination (FSI) SPADs or a flip chip bonding process for backside illumination (BSI) SPADs. For example, Nagano et al. (U.S. Pat. No. 9,435,686 B2) illustrates the general FSI SPAD architecture in which TSV (see e.g. TE in FIG. 2) are required. As will be further detailed herein, the use of TSV not only reduces the photosensitive surface of the SPAD array but also adds parasitic nodes in the readout circuitry which may negatively impact the timing jitter. Moreover, the TSV adds some processing steps, making the manufacturing more complicated and more expensive.

As is known in the art, TSV are generally only required for FSI architectures as a BSI layout, see e.g. Mandai et al. (US 2018/0090536 A1), necessarily includes the cathode region on the backside of the SPAD and thus may be directly connected to the interconnecting layer (i.e. the layer providing connection between the SPADs and the CMOS). However, in BSI architectures, the SPAD layer substrate must be thinned down to detect photons at the wavelength of interest. Even with thinning, the photo-generated carriers must drift several microns to reach the SPAD junctions, which greatly limits the reduction of timing jitter that can be achieved. While a significantly greater timing jitter may be acceptable for a use in a mobile device camera system, as described in Mandai et al., it may not be optimal for most other applications in which the timing resolution is paramount (e.g. medical imaging, liquid xenon or argon detectors, etc.). Additionally, the manufacturing of a device as detailed in Mandai et al. may be complex and costly as the isolating trenches and their sidewalls may require specific designs in which their cross-section may vary throughout the length of the trench, such that the induced polarisation in the SPAD structure allows for the electron to drift towards the active section of the SPAD.

### SUMMARY

The applicant has found that using a new thinned down frontside 3D SPAD array architecture in a 3D digital SiPM or 3D analog SiPM, with direct interconnect layers between the SPAD and the CMOS readout, removed the need to have through-silicon-vias. In addition to removing the need of TSVs, the direct connection provides a more uniform time for the development of the avalanche and its propagation to an electrical contact thus providing low timing jitter operation of the SPADs.

Applicant has further discovered that extended isolation trenches through the entire thickness of the thinned down frontside-illuminated SPAD substrate enables both the SPAD cell to be electrically and optically isolated from the other SPAD cells. As such, the crosstalk is minimized, and direct backside connection is possible.

A first broad aspect is a vertically integrated frontside-illuminated single photon avalanche diode (SPAD) array comprising: a substrate; a plurality of layers of integrated circuitry disposed on the substrate, the circuitry comprising: a data bus; data bus contacts connected to the data bus; surface contacts disposed in an array; and readout circuitry connected to the surface contacts and to the data bus; a first material layer of a n-type semiconductor disposed on the surface contact; a second material layer of a p-type semiconductor disposed on the first material layer, wherein an arrangement of the first and second material layer defines a SPAD junction; a top surface electrode disposed on the second material layer; and opto-electrical insulation barriers filling a space defined by trench walls extending through the first and second material layer to optically and electrically insulate individual SPAD cells of the SPAD array from one another.

In some embodiments, the circuitry further comprises a top surface contact to a side of the SPAD cells for providing external control over a voltage on the top surface electrode.

In some embodiments, the top surface electrode comprise a metal grid placed over the opto-electrical insulation barriers, the metal grid being operable to bias all SPAD to the same voltage.

In some embodiments, the second material layer is a p-type semiconductor and is sufficiently thin to bring a multiplication region within a first thickness of about 100 nm from a top surface of the second material layer, whereby the SPAD array is suitable for working with a wavelength of about 500 nm to 350 nm.

In some embodiments, the second material layer is an n-type semiconductor and the first material is a p-type semiconductor sufficiently thick to extend a sensitivity of the SPAD array for working with a wavelength of about 1000 nm to 500 nm.

In some embodiments, the arrangement of the first and second material layer is configured to extend a sensitivity of the SPAD array for working with a wavelength below 350 nm.

In some embodiments, the SPAD array further includes a third material layer disposed on the second material layer, wherein the third material layer is configured to drift surface photoelectrons to the SPAD junction.

In some embodiments, the third material layer is a highly boron doped silicon layer.

In some embodiments, the opto-electrical insulation barriers are made of in-situ doped polysilicon.

In some embodiments, the surface contacts extend over more than one half of an area of the first material layer covers the surface contacts to provide a high conductivity path such that the timing jitter intrinsic to the formation and propagation of the avalanche is reduced.

In some embodiments, the surface contacts of the circuitry comprise a Germanium interconnecting layer.

In some embodiments, each of the SPAD cells in the array are separated by a pitch of 50 to 100 μm.

In some embodiments, a seal ring surrounds a whole die and provides mechanical support.

In some embodiments, the seal ring is made of aluminum-germanium composite.

### BRIEF DESCRIPTION OF THE DRAWINGS

The invention will be better understood by way of the following detailed description of embodiments of the invention with reference to the appended drawings, in which:

FIG. 1A is a schematic of a prior art frontside illumination SPAD architecture comprising a through-silicon-via;

FIG. 1B is a schematic of a prior art backside illumination SPAD architecture comprising a flip chip bonding;

FIG. 2 is a schematic of an exemplary frontside illumination SPAD in which the connection with the CMOS is done through direct interconnect layers;

FIG. 3 is a schematic of an exemplary SPAD array with multiple SPAD cells connected to a CMOS wafer;

FIG. 4 is a schematic of an exemplary SPAD array with multiple SPAD cells connected to a CMOS wafer with a more detailed view of the interconnection layers and an expanded view of the electric field profile between the anode and cathode;

FIG. 5 is a top-view illustration of an exemplary photodetector pixel structure comprising a SPAD array positioned over a CMOS readout substrate;

FIG. 6 is a cross-section schematic of an exemplary photodetector pixel structure comprising a SPAD array and an expanded view of a SPAD cell of the SPAD array;

FIG. 7 is a scanning electron microscope (SEM) cross section of an exemplary SPAD cell of a SPAD array shown as a line drawing;

FIG. 8A is a block diagram illustrating the communication path between a SPAD and the CMOS pad output; and

FIG. 8B is a block diagram illustrating the communication path between a SPAD and the CMOS pad output where the quenching circuit is not part of the CMOS circuitry layer.

### DETAILED DESCRIPTION

The present disclosure relates to a frontside-illuminated single-photon avalanche diode detector 3D architecture with no through-silicon-vias and in which every SPAD cell is optically and electrically insulated. The leading argument to use 3D vertical integration is the possibility to choose the best process to design and fabricate the SPAD array and to independently choose the most appropriate CMOS process for the readout electronics. Optimal technologies choice will bring optimal performances of both SPADs (photodetection efficiency, correlated noise) and optimal capabilities of the CMOS electronics. But more than this, the 3D integration allows for higher photosensitive fill-factor, a higher degree of integration into systems (e.g., large-scale photodetectors) and for a less capacitive and more uniform connection between the SPAD and the readout circuit to reach ultimate performances in timing resolution or power dissipation.

While the SPAD technology is described herein, the CMOS process is typically chosen on the basis of its cost, the complexity of the readout electronics per SPAD desired, the compatibility with 3D integration and the availability of wafers (multi-project wafer run, prototyping run or production run). Advanced 3D integration processes usually require the handling of full wafers (as opposed to die-to-die assembly techniques). The 3D integration process may further be compatible with a standard CMOS finishing layer such as aluminum pad or under bump metallization. As it would be understood by someone skilled in the art, the details of the CMOS circuitry (TDC, quenching circuit, readout electronics) does not impact the overall 3D integration structure, so it will not be further discussed herein.

In the prior art, 3D frontside illuminated SiPM systems typically use through-silicon-vias to replace wire bonds to connect all input and output signals from the CMOS wafer to the acquisition layer (e.g., connecting the SPAD anode or cathode with the CMOS). Through-silicon-vias are commonly used in high-end microelectronic devices but are often vendor-specific and thus limits the selection of CMOS technologies that may be used in combination with the photodetector. Compared to a 2D SiPM architecture, which does not need TSVs, the addition of the vias increases significantly manufacturing costs and the complexity of such. Additionally, the use of through-silicon-vias lowers the photosensitive fill factor in a SPAD array, and using an architecture without vias may therefore increase the photosensitive fill factor.

Some prior art references feature architectures without TSVs. For example, Richter et al. have proposed, in US20110095388, a bump bonded SiPM. The structure taught by Richter allows high-density SPAD arrays, where each cells are connected to a common node via a resistive depleted channel acting as a quenching resistor (i.e analog SiPM architecture). Connection to multiple CMOS electronics (e.g., wired-OR triggers, TDC, hit-matrix readout, validation logic, etc.) would be limited by the resistive channel, by the electrical crosstalk and by the leakage that would occur between adjacent cells. Also, this design typically presents higher noise from SPAD optical crosstalk and delayed crosstalk, that could be lowered by optical isolation trench on the frontside of the device.

One of the improvements of the structure described herein is the use of opto-electrical isolation trenches surrounding each SPAD pixel. In combination with the frontside illuminated and TSV-less 3D integration, the new proposed architecture provides fast timing UV and visible light detection along with noise reduction and reduced device manufacturing complexity.

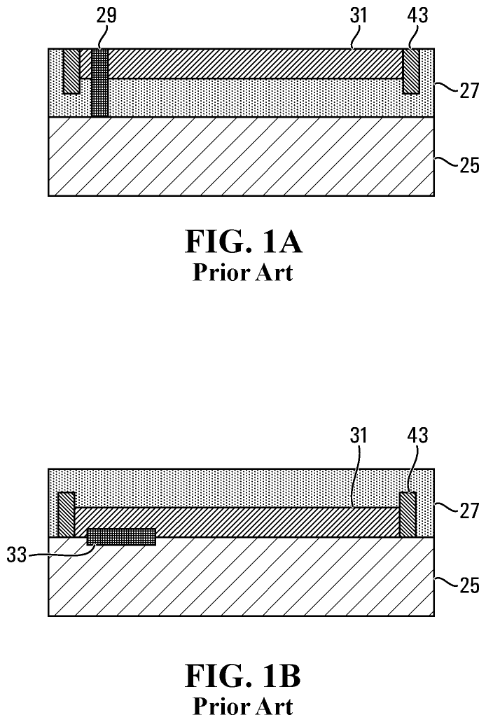

Now referring to FIG. 1A which is a schematic of a prior art frontside illumination SPAD architecture comprising a through-silicon-via 29. This figure illustrates the most common architecture for current frontside illumination digital SiPM. In such a structure, the via 29 connects the SPAD reading/quenching electrode 31 of the SPAD to the CMOS wafer 25. The SPAD reading/quenching electrode 31 may be the anode or the cathode depending on the architecture of the cell. A person skilled in the art will appreciate that references to a cathode or an anode is not limitative and should be understood as only one possibility which may be equivalently achieved by using the opposed architecture. As a matter of fact, the SPAD reading/quenching electrode 31 may be either an anode or cathode, as it is possible to either apply a positive bias on the cathode and quench on the anode or to quench on the cathode and apply a negative bias on the anode. Additionally, it remains possible to read on either side, whether from DC when coupled on the quenching side or from AC when coupled on the voltage bias side. Both architecture are therefore equivalents. As such, the SPAD reading/quenching electrode 31 may be of either dopant type.

The SPAD reading/quenching electrode 31 is comprised inside the SPAD layer 27, which may include any required buildup of p-type and n-type sections. The structure may further include electrical insulation of the SPAD from the CMOS wafer 25 by a thin surrounding insulation layer, which may be made of silicon dioxide (SiO2). In such prior art configuration, the SPAD layer and CMOS wafer are typically continuous and each SPAD reading/quenching electrode 31 are insulated from each other using spacing and/or trenches. As each SPAD reading/quenching electrodes 31 are connected through their respective vias 29, the CMOS may detect which one was triggered by a photon. However, in these prior art configurations, photons may trigger more than one SPAD cells, since secondary photons are emitted from the initial avalanche. False positives may therefore be sensed and thus the SPAD array may produce unreliable data. The introduction of shallow optical isolation trenches 43 is the usual technique to access the optical crosstalk. However, some studies have demonstrated that shallow trenches are not always efficient at blocking secondary photons as they may reflect on the backside of the SPAD substrate. As described herein, the use of full thickness trenches is a significant improvement over the shallow trenches, as it removes the possibility for secondary photons to find an unblocked path to an adjacent SPAD cell.

FIG. 1B is a similar prior art exemplary structure of a backside illumination SPAD architecture comprising a flip chip like bonding 33. In this architecture, the SPAD is a reverse-biased semiconductor with the SPAD reading/quenching electrode 31 on the CMOS 25 side of the SPAD layer 27. In this reverse-biased detector, a flip chip 33 provides a connection with the CMOS 25 electronics. Similar to the prior art embodiment described in FIG. 1A, crosstalk noise is an issue for the SPAD array and typically shallow trenches 43 are introduced to partially address this issue.

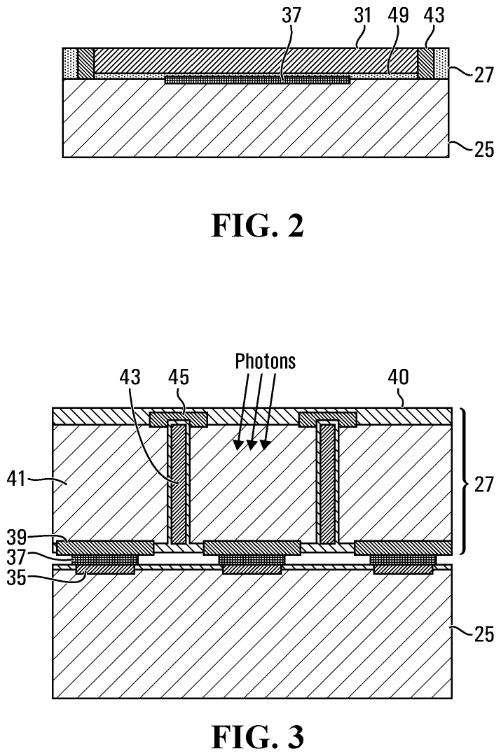

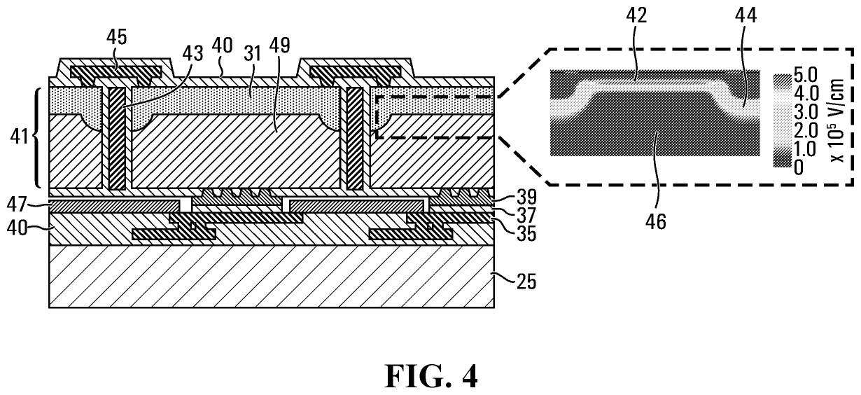

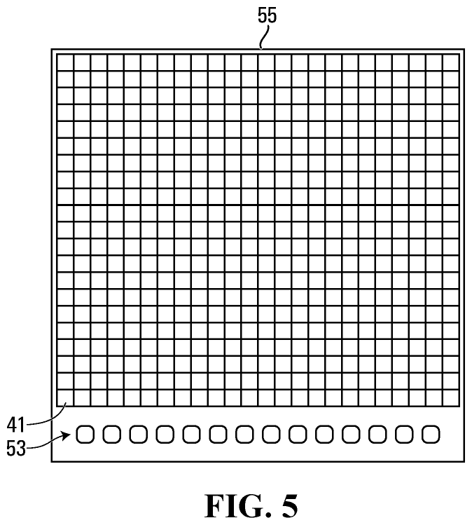

Now referring to FIG. 2 which is a schematic of an exemplary frontside illumination SPAD in which the connection with the CMOS is done through interconnecting layers. This architecture does not require any through-silicon-vias to connect the SPAD reading/quenching electrode 31 of the SPAD layer 27 to the CMOS layer 25, through the oppositely doped electrode 49 and interconnect layer 37. The interconnect layer 37 may have a significant size with regards to the extent of the area of the junction between the semiconductor and the CMOS. For example, the interconnect layer 37 may occupy at least half of the surface area available for a SPAD of the SPAD array. Increasing the available contact area, when compared to the prior art solutions, provides significant benefits in terms of reducing the timing jitter. This may primarily be due to the increase of the high conductivity surface providing connectivity between each SPAD of the SPAD array and the readout circuitry of the CMOS. A person skilled in the art will appreciate that the area covered by the interconnect may vary depending on manufacturing requirements. FIGS. 3 and 4 present exemplary detailed views of such SPAD.

The SPAD array for a 3D integrated device can benefit from the same advancements made in analog SiPM to improve their performances in terms of photon detection efficiency (PDE), single photon timing resolution (SPTR) and noise. More specifically, the structure described in the FIG. 4 can be designed either with a p+n or n+p dopant profile, depending on the wavelength of interest (deep-blue/UV range for p+n versus visible/NIR range for n+p). For example, in order to improve the PDE, knowing that electrons have a greater probability than holes to start an avalanche for a given relative excess voltage, it may be preferable to have the photons absorbed in the p-side of the junction. When working with a wavelength in the green and below (500 nm to 350 nm), photoelectrons are created closer to the silicon surface than for longer wavelengths. This justifies a shallow p+n junction design. Hence the absorption region may be very thin to bring the multiplication region within the first ˜100 nm from the surface. When working with a wavelength toward the red or near infrared (500 nm to 1000 nm), the photoelectron distribution extends deeper into the silicon. This justifies a shallow n+p design with the p-side being sufficiently deep to collect all photoelectrons (i.e., thick absorption region).

However, in silicon, even with a very shallow p+n junction, it is not possible to maintain the PDE to an acceptable value when sensitivity in deep-UV range is required, like in the case of scintillation light from liquid Xe and liquid Ar. Photons below 350 nm penetrate less than 10 nm below the silicon surface so band profile engineering is needed to drift surface photoelectrons to the SPAD junction. A person skilled in the art will appreciate that using an adequate top surface treatment may allow the SPAD array to be sensitive to wavelengths shorter than 350 nm, such as with deep-UV wavelengths of around 125 nm.

Jet Propulsion Laboratory (JPL) pioneered the use of low-temperature molecular beam epitaxy (MBE) on backside-illuminated CCDs to improve their deep UV quantum efficiency. Basically, for a p+n diode, a few atomic layers of highly boron-doped silicon are epitaxially grown on the top of the silicon to create a peak in the band profile some 2 nm to 4 nm below the surface. This increases the probability of collecting photoelectrons that have been generated near the surface, while trapping undesired surface thermal electrons.

In terms of noise, the junction must be properly designed (electric field shape) to avoid band-to-band tunneling and field-enhanced Shockley-Read-Hall generations. Damages and defects during the SPAD processing must be minimised. For instance, diffusion doping is preferred over implantation doping to reduce induced defects. Detailed information on the noise in SPAD and SPAD array is available in the literature and can be transposed to the proposed 3D FSI SPAD architecture.

The CMOS quenching circuit and the interconnect layer in the 3D FSI SPAD architecture can be designed to minimise the reading node capacitance and the charge per avalanche. This is beneficial in terms of noise since crosstalk and after pulsing noises scale with the charge per avalanche. The CMOS electronics can also be used to implement a hold off time for each individual SPAD when it triggers. This let the deep energy traps responsible for after pulsing relax before biasing the SPAD for the next photon detection.

The optical isolation trenches are used to reduce the crosstalk noise and to enable a closer SPAD integration in array, which increase the overall device photosensitive area (fill factor). The material filling the trenches must absorb and/or block the secondary photons emitted by SPAD cells during avalanche.

FIGS. 3 and 4 are schematics of an exemplary SPAD array with multiple SPAD cells 41 connected to a CMOS wafer 25. FIG. 3 illustrates a SPAD array with a number of SPAD cells 41 separated by opto-electrical insulation trenches 43 and FIG. 4 provides a refined view of the SPAD junction. In the preferred embodiment, the opto-electrical insulation trenches 43 are made of in-situ doped polysilicon and silicon dioxide. As described herein, these trenches are required to minimize optical crosstalk while further acting as electrical separators between the SPAD cells. The trenches 43 are thermally oxidized and annealed before the polysilicon filling, to prevent noise injection from sidewall and to insulate SPAD cells from each other. They must be as narrow as possible to minimize the light detection dead area. Finally, such an opto-electrical insulation trench design allows the avalanche profile to be fully vertical (no lateral signal propagation), leading to a significant improvement in detection timing resolution. A person skilled in the art will understand that a different material choice for the opto-electrical insulation may be used without departing from the teachings of this disclosure.

While described as being made of in-situ doped polysilicon, including silicon dioxide, the opto-electrical insulation trenches 43 may be made of any other insulating material. A person skilled in the art will further understand that the insulation may be provided by one or more layers of insulating material, for example one layer providing electrical insulation while a second layer provides optical insulation.

Each SPAD cell's 41 reading/quenching electrode is interconnected by a top metal grid 45 which may be used to short and bias all the SPAD reading/quenching electrodes at the same time. In order to connect to the CMOS layer 25 without a via, the SPAD cells 41 use three separate components. In the preferred embodiment, an in-situ doped polysilicon acts as the SPAD connector 39 that connects the SPAD cell 41 with an interconnecting layer 37 (which may be a germanium layer, as it is known in the art and common in CMOS technologies due to its bonding properties with aluminum connections). The SPAD connector 39 has high conductivity and ideally extends over the whole SPAD lateral dimensions thus minimizing timing jitter due to avalanche propagation. The interconnecting layer 37 can be of smaller area because of its event higher conductivity. The interconnecting layer 37 is further connected to the CMOS wafer's 25 top metal connections 35. It will be understood by someone skilled in the art that different material choices may be used without departing from the teachings of this disclosure.

FIG. 4 is a schematic of an exemplary SiPM architecture with multiple SPAD cells connected to a CMOS wafer or die with a more detailed view of the interconnection layers. Similar to FIG. 3, the SPAD cells are herewith presented with both their SPAD reading/quenching electrode 31 (which may be of a first dopant type, such as a p+ implant section with p− lateral implants to avoid lateral breakdown) and their oppositely doped electrode 49 (which may be of a second dopant type, such as an n-type section). Each SPAD reading/quenching electrode 31 is connected through the top metal grid 45 and each SPAD cell is optically and electrically insulated through the use of opto-electrical trenches 43. Each SPAD cell is further connected to the CMOS wafer 25 through the SPAD connector 39, the interconnecting layer 37 and the CMOS' top metal connections 35. Additionally, in order to provide increased electrical insulation or increased mechanical strength between the SPAD cells and the CMOS wafer 25, a layer of insulating material 47 may be added in between the SPAD-CMOS connections. In the preferred embodiment, the layer of insulating material may be silicon nitride.

FIG. 4 further shows the electric field profile between the SPAD reading/quenching electrode 31 (p+ implanted section) and the oppositely doped electrode 49. In a FSI SPAD as illustrated in this embodiment, the electrode 31 may be the anode (p-type semiconductor) and the electrode 49 may be the cathode (n-type semiconductor). In this embodiment, the highest electric field region 42 (˜5.0×10⁵ V/cm) is the avalanche region. The electric field strength varies depending on the vicinity of the avalanche region (low strength represented by 46 and medium strength by 44).

It will be understood that the manufacturing process may further include additional insulation material 40, such as silicon dioxide, between the different elements of the SPAD cells and the CMOS, such that better electrical insulation is achieved.

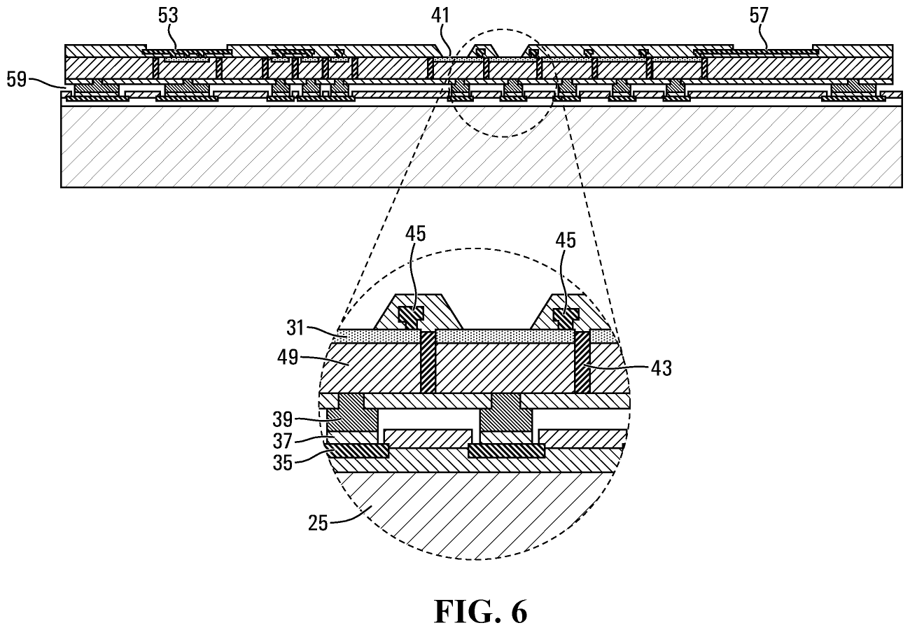

Now referring to FIG. 5, which is a top-view illustration of an exemplary photodetector pixel die 55 comprising a SPAD array. In this exemplary pixel sensor layout, SPAD cells 41 are disposed in an array configuration. Although not represented in this figure, each SPAD cell 41 is surrounded by a trench and their reading/quenching electrodes are all interconnected by a top metal grid to provide SPAD polarization. The control pads 53 are located on a single side of the pixel sensor. Each SPAD cell 41 is connected to the CMOS wafer independently of the other cells. Also not represented herein, a seal ring may be added to surround the whole die and provide mechanical support for microfabrication requirements.

While FIG. 5 illustrates a SPAD array in a square configuration, it will be understood that any shape may be used without departing from the teachings of this disclosure. For some applications, a honeycomb, hexagonal or circular shape array may be used.

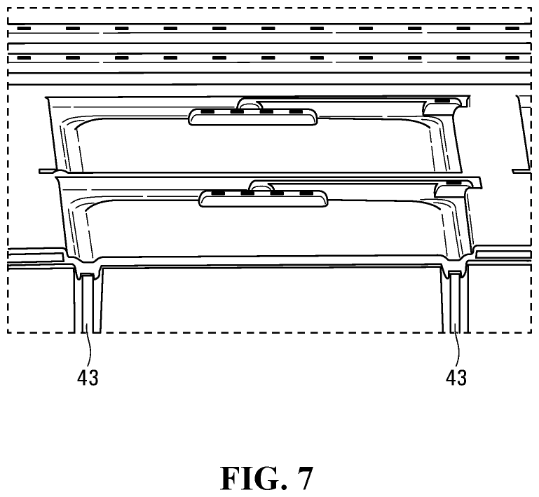

FIG. 6 is a cross-section schematic of an exemplary photodetector pixel structure comprising a SPAD array. As described herein, the seal ring 59 may be added to the SiPM die to provide structural support for the manufacturing process. In the preferred embodiment, the seal ring may be made of aluminum-germanium composite. CMOS pad 53 and SPAD cells 41 are further shown in FIG. 6. The top metal grid to short all the SPAD cells 41 reading/quenching electrodes may be controlled through a SPAD pad 57. In this exemplary buildup, each of the SPAD cells 41 in the array may be separated by a pitch of 50 to 100 μm. Lower pitch separation, for example as low as 5 μm may be achievable depending on the manufacturing process and may be useful for a number of applications.

FIG. 6 further includes an expanded view of a SPAD cell 41 from the SPAD array. In this embodiment, the layers of the SPAD are configured as described in FIG. 4. As such, the SPAD reading/quenching electrode 31 of each SPAD cell are connected through the top metal grid 45. The SPAD layer further includes the oppositely doped electrode 49 and the SPAD connector 39. The interconnecting layer 37 connects the SPAD to the top metal connections 35 of the CMOS wafer 25. Each SPAD cells 41 from the SPAD array are separated by the opto-electrical insulation trenches 43.

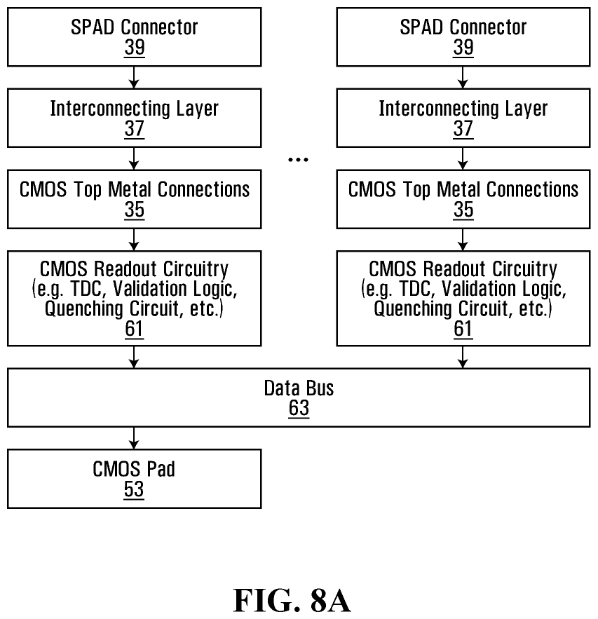

FIG. 7 shows a line drawing of a scanning electron microscope (SEM) cross section of the first prototype built following the disclosed SPAD configuration. The cross-section shows a SPAD cell surrounded by the opto-electrical insulation trenches 43. The top metal grid connecting the SPAD reading/quenching electrodes may further be seen on both SPAD cells represented in FIG. 7.

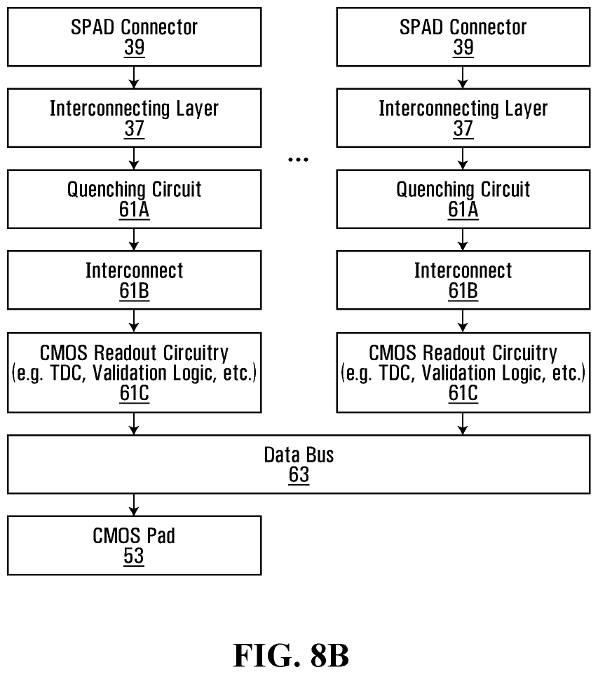

Now referring to FIG. 8A, which illustrates a number of layers of integrated circuitry including interconnection circuit elements providing a communication path between a SPAD cell and the CMOS architecture, up to the CMOS pad. The SPAD is connected to the circuitry through a surface contact, such as the SPAD connector 39. As detailed in the description of FIG. 4, the SPAD connector 39 may interface with an interconnecting layer 37, which is further interfacing with the CMOS top metal connections 35. In other embodiments, the SPAD connector 39 may directly interface with the CMOS top metal connections 35. These top metal connections 35 provide electrical pathways to any CMOS readout circuitry 61 included in the CMOS wafer 25. The CMOS readout circuitry 61 may include any electronics required to operate the SPAD array, such as a time-to-digital converter (TDC), validation logics, quenching circuits, etc. The aforementioned communication structure may be repeated for each SPAD cell in a SPAD array.

The CMOS readout circuitry 61 of each SPAD cell is connected to the CMOS data bus 63 through data bus contacts. Any number of SPAD cells of the SPAD array may be connected to a CMOS pad 53, such that the signals of any number of SPAD cells of the SPAD array may be processed and may be communicated to the system in which the SPAD is operating. A person skilled in the art will appreciate that the structures between the SPAD connector 39 and the CMOS pad 53 may vary without departing from the teachings of this disclosure. For example, the readout circuitry dedicated to each SPAD may not necessarily be located in the CMOS below the SPAD cell (e.g. it may be located on a side of the SPAD cell and or SPAD array).

FIG. 8B illustrates another embodiment of the layers of integrated circuitry and interconnection circuit elements between the SPAD connector 39 and the CMOS pad 53 in which the quenching circuit 61A is not part of the CMOS circuitry. The SPAD is connected to the circuitry through a surface contact, such as the SPAD connector 39. The SPAD connector 39 may further interface with an interconnecting layer 37, which provides electrical pathways to a quenching circuit 61A. The quenching circuit 61A may interface with CMOS readout circuitry 61C through an interconnect 61B. The CMOS readout circuitry 61C may include any electronics required to operate the SPAD array, such as a time-to-digital converter (TDC), validation logics, etc. The aforementioned communication structure may be repeated for each SPAD cell in a SPAD array and may be connected to a CMOS data bus 63 through data bus contacts such that it may be accessed at a single CMOS pad 53. A person skilled in the art will appreciate that the readout circuitry may not communicate in a single data bus 63 and may otherwise be read at any number of connection pads.

What is claimed is:

1. A vertically integrated frontside illuminated single photon avalanche diode (SPAD) array comprising:
a substrate;
a plurality of layers of integrated circuitry disposed on said substrate, said integrated circuitry comprising interconnection circuit elements including surface contacts disposed in an array;
a first material layer of a n-type semiconductor disposed on said surface contact;
a second material layer of a p-type semiconductor disposed on said first material layer, wherein an arrangement of said first and second material layer defines a SPAD junction;
a top surface electrode disposed on said second material layer; and
opto-electrical insulation barriers filling a space defined by trench walls extending through said first and second material layer to optically and electrically insulate individual SPAD cells of said SPAD array from one another.

2. The SPAD array as defined in claim 1, wherein said interconnection circuit elements further comprises a data bus, data bus contacts connected to said data bus, surface contacts connected to said data bus and readout circuitry connected to said surface contacts and to said data bus.

3. The SPAD array as defined in claim 1, wherein said interconnection circuit elements further comprise a top surface contact to a side of said SPAD cells for providing external control over a voltage on said top surface electrode.

4. The SPAD array as defined in claim 1, wherein said top surface electrode comprise a metal grid operable to bias all SPAD to the same voltage.

5. The SPAD array as defined in claim 4, wherein said metal grid is placed over said opto-electrical insulation barriers.

6. The SPAD array as defined in claim 1, wherein said second material layer is sufficiently thin to bring a multiplication region within a first thickness of about 100 nm from a top surface of said second material layer, whereby said SPAD array is suitable for working with a wavelength of about 500 nm to 350 nm.

7. The SPAD array as defined in claim 1, wherein said arrangement of said first and second material layer is configured to extend a sensitivity of said SPAD array for working with a wavelength below 350 nm.

8. The SPAD array as defined in claim 7, further comprising a third material layer disposed on said second material layer, wherein said third material layer is configured to drift surface photoelectrons to said SPAD junction.

9. The SPAD array as defined in claim 8, wherein said third material layer is a highly boron doped silicon layer.

10. The SPAD array as defined in claim 1, wherein said opto-electrical insulation barriers comprise in-situ doped polysilicon such that crosstalk between SPADs is reduced.

11. The SPAD array as defined in claim 1, wherein said surface contacts extend over more than one half of an area of said first material layer to provide a high conductivity path such that the timing jitter intrinsic to the formation and propagation of the avalanche is reduced.

12. The SPAD array as defined in claim 1, wherein said surface contacts of said circuitry comprise a Germanium interconnecting layer.

13. The SPAD array as defined in claim 1, wherein each of the SPAD cells in the array are separated by a pitch of 5 to 100 μm.

14. The SPAD array as defined in claim 1, wherein a seal ring surrounds a whole die and provides mechanical support.

15. The SPAD array as defined in claim 14, wherein the seal ring is made of aluminum-germanium composite.
